(19) United States
(12) Patent Application Publication
(10) Pub. No.: US 2022/0081758 A1
(43) Pub. Date: Mar. 17, 2022

(54) METHODS AND APPARATUS FOR IN-SITU DEPOSITION MONITORING

(71) Applicant: APPLIED MATERIALS, INC., Santa Clara, CA (US)

(72) Inventors: Xiaodong WANG, San Jose, CA (US); Michael Charles KUTNEY, Santa Clara, CA (US); Varoujan CHAKARIAN, San Jose, CA (US); Jianxin LEI, Fremont, CA (US); Rongjun WANG, Dublin, CA (US)

(21) Appl. No.: 17/019,949

(22) Filed: Sep. 14, 2020

(51) Int. Cl. C23C 14/54; C23C 14/50; C23C 14/24

(52) U.S. Cl. CPC C23C 14/54; C23C 14/24; C23C 14/50

(57) ABSTRACT

Methods and apparatus that monitors deposition on a shutter disk in-situ. In some embodiments that apparatus may include a process chamber with an internal processing volume, an enclosure disposed external to the internal processing volume where the enclosure accepts a shutter disk when the shutter disk is not in use in the internal processing volume, a shutter disk arm that moves the shutter disk back and forth from the enclosure to the internal processing volume, and at least one sensor integrated into the enclosure. The at least one sensor is configured to determine at least one film property of a material deposited on the shutter disk after a pasting process in the internal processing volume.

### FIELD

Embodiments of the present principles generally relate to semiconductor processing of semiconductor substrates.

### BACKGROUND

During the formation of integrated circuits, many different layers of materials may be used as the building blocks of the circuits. In some circuit structures, slight differences in film properties may result in low performing circuits. Often times, sample wafers are pulled after processing in a chamber and sent to a lab for analysis. The ex-situ type testing may cause extended production delays as the testing frequently requires days or even a week to complete. Some processes use a shutter disk to protect the substrate support surface during pasting. The inventors have observed that when the pasting is performed, not only are the walls of the process chamber coated but the shutter disk is coated as well. The inventors have found that the deposition on the shutter disk may provide an indicator of the quality of the deposition environment of the process chamber.

Accordingly, the inventors have provided improved methods and apparatus for monitoring depositions on a shutter disk.

### SUMMARY

Methods and apparatus for in-situ monitoring of pasting depositions on a shutter disk are provided herein.

In some embodiments, an apparatus for monitoring deposition includes a process chamber with an internal processing volume, an enclosure disposed external to the internal processing volume where the enclosure is configured to accept a shutter disk when the shutter disk is not in use in the internal processing volume, a shutter disk arm configured to move the shutter disk back and forth from the enclosure to the internal processing volume, and at least one sensor integrated into the enclosure where the at least one sensor is configured to determine at least one film property of a material deposited on the shutter disk after a pasting process in the internal processing volume.

In some embodiments, the apparatus may further include a memory disposed in the enclosure that accepts data associated with the at least one film property from the at least one sensor, a communication port disposed in the enclosure that connects the memory or the at least one sensor to an external device, wherein the communication port transfers stored data from the memory or real-time data from the at least one sensor and includes wired or wireless data transfers, wherein the at least one sensor includes a spectroscopy sensor, a film morphology sensor, or a film thickness sensor, wherein the spectroscopy sensor includes an X-ray fluorescence (XRF) analyzer that determines the at least one film property of the material deposited on at least an upper surface the shutter disk, wherein the material is magnesium oxide (MgO) and the at least one film property includes a magnesium-to-oxygen ratio of the MgO, wherein the shutter disk arm is configured to rotate the shutter disk within the enclosure such that more than one location on a surface of the shutter disk is exposed to the at least one sensor, wherein the at least one sensor is configured to detect the at least one film property as the shutter disk enters the enclosure, wherein the enclosure includes a movable sealing plate that divides an internal volume of the enclosure from the internal processing volume, and/or wherein the enclosure is configured to be pressurized independent of the internal processing volume such that data obtained by the at least one sensor with regard to the at least one film property is enhanced.

In some embodiments, an apparatus for monitoring deposition includes a process chamber with an internal processing volume, an enclosure disposed external to the internal processing volume where the enclosure is configured to accept a shutter disk when the shutter disk is not in use in the internal processing volume, a shutter disk arm configured to move the shutter disk back and forth from the enclosure to the internal processing volume, and at least one sensor integrated into the shutter disk where the at least one sensor is configured to determine at least one film property of a material deposited on the shutter disk after a pasting process in the internal processing volume.

In some embodiments, the apparatus may further include a power source integrated into the shutter disk, wherein the power source is configured to energize the at least one sensor and an inductive charging system integrated into the enclosure, wherein the inductive charging system is configured to energize the power source for the at least one sensor when the shutter disk is placed within the enclosure, a first memory integrated into the shutter disk, wherein the first memory is configured to store data associated with the at least one film property from the at least one sensor, a second memory disposed in the enclosure that accepts data associated with the at one least film property from the first memory via a wired or wireless transfer when the shutter disk is placed within the enclosure, a communication port disposed in the enclosure that connects to the second memory or to the first memory, wherein the communication port transfers stored data from the second memory or first memory and is configured to perform wired or wireless data transfers, wherein the at least one sensor is a plurality of sensors forming a sensor array on the shutter disk, wherein the sensor array includes a resonance array configured to determine a thickness of the material based on frequency shifts, and/or wherein the material is magnesium oxide (MgO) and the at least one sensor is configured to determine a magnesium-to-oxygen ratio of the MgO.

In some embodiments, an apparatus for monitoring deposition includes an enclosure configured to be mounted external to an internal processing volume of a processing chamber, wherein the enclosure is configured to accept a shutter disk when the shutter disk is not in use in the internal processing volume, at least one sensor integrated into the enclosure where the at least one sensor is configured to determine at least one film property of a material deposited on the shutter disk after a pasting process in the internal processing volume, a memory disposed in the enclosure, wherein the memory is configured to accept data associated with the at least one film property from the at least one sensor, and a communication port disposed in the enclosure, wherein the communication port transfers stored data from the memory or real-time data from the at least one sensor and includes wired or wireless data transfers.

In some embodiments, the apparatus may further include wherein the at least one sensor includes an X-ray fluorescence (XRF) analyzer that is configured to determine a magnesium-to-oxygen ratio of MgO deposited on the shutter disk or a micro-electromechanical system sensor configured to determine thickness of a deposition layer on the shutter disk.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts a schematic cross-sectional side view of a process chamber in accordance with some embodiments of the present principles.

FIG. 2 depicts a schematic cross-sectional side view of a portion of a process chamber in accordance with some embodiments of the present principles.

FIG. 3 depicts an isometric view of a process chamber with a sensor integrated in a shutter disk enclosure in accordance with some embodiments of the present principles.

FIG. 4 depicts a top down view of a process chamber in accordance with some embodiments of the present principles.

FIG. 5 depicts a schematic cross-sectional side view of a portion of a process chamber in accordance with some embodiments of the present principles.

FIG. 6 depicts an isometric view of a process chamber with a memory and inductive charging system integrated into a shutter disk enclosure in accordance with some embodiments of the present principles.

FIG. 7 depicts a shutter disk with integrated sensors interacting with an inductive charging system in accordance with some embodiments of the present principles.

FIG. 8 depicts a top down view of a shutter disk with a linearly aligned sensor array pattern in accordance with some embodiments of the present principles.

FIG. 9 depicts a top down view of a shutter disk with a dispersed sensor array pattern in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and apparatus provide in-situ monitoring of pasting depositions. The depositions on a shutter disk are used to determine film properties of pasting processes. In some embodiments, the deposition on the shutter disk is analyzed by sensors in a shutter garage or by sensors on a shutter disk. Using the shutter disk to analyze the depositions, provides in-situ deposition evaluation without major chamber modifications (shutter disk is already part of the chamber design). Because the shutter disk is used to protect the substrate support surface, the shutter disk is in the same position as a wafer and data obtained from the shutter disk can be treated as data from the wafer. In some embodiments that utilize a sensor array, multiple data points can be obtained to provide a wafer deposition profile, indicating, for example, deposition uniformity and the like. Another advantage is the shutter disk allows in-situ evaluations without requiring a wafer to be sent out for testing which can delay production by days or a week. Yet another advantage of the in-situ evaluation is the shutter disk can be evaluated more frequently or as needed to ensure continually optimized performance of the process without unduly delaying production.

Some deposition processes require a high degree of accuracy in composition to provide a high-performance semiconductor structure such as, for example, a magnetoresistive random-access memory (MRAM) stack. The MRAM stack is very sensitive to changes in the magnesium-to-oxygen ratio of the very thin (<10 angstroms) magnesium oxide (MgO) layer. If a test wafer needs to be removed from the chamber for ex-situ testing, the test wafer will easily oxidize when exposed to the environment, skewing test results. The present methods and apparatus allow for in-situ monitoring of the MgO layer magnesium-to-oxygen ratio without having to send out a test wafer for analysis, increasing test accuracy and performance of the MRAM without ex-situ testing delays. In addition, adjustments can be made based on the in-situ results, allowing real-time process flow adjustments to be made (e.g., performing additional pasting or the like to adjust magnesium-to-oxygen ratios, etc.) to increase performance and yield. The present methods and apparatus may also be used for other semiconductor structures such as dynamic random access memory (DRAM), logic structures, and/or interconnects and the like. The various sensor types incorporated may be used to determine the morphology of the film, the thicknesses of the film, and other parameters that may be used to optimize performance of the film and the structure.

As used herein, pasting includes deposition of materials when a shutter disk has replaced a substrate on a substrate support. The deposition with the shutter disk on the substrate support may be performed, for example, as part of a particle reduction effort, as part of a method to improve film performance and/or purity, and/or as part of a process to test deposition material. As the present methods and apparatus provide the ability to test depositions quickly and frequently in-situ, pasting processes may be used strictly for deposition of materials for testing purposes.

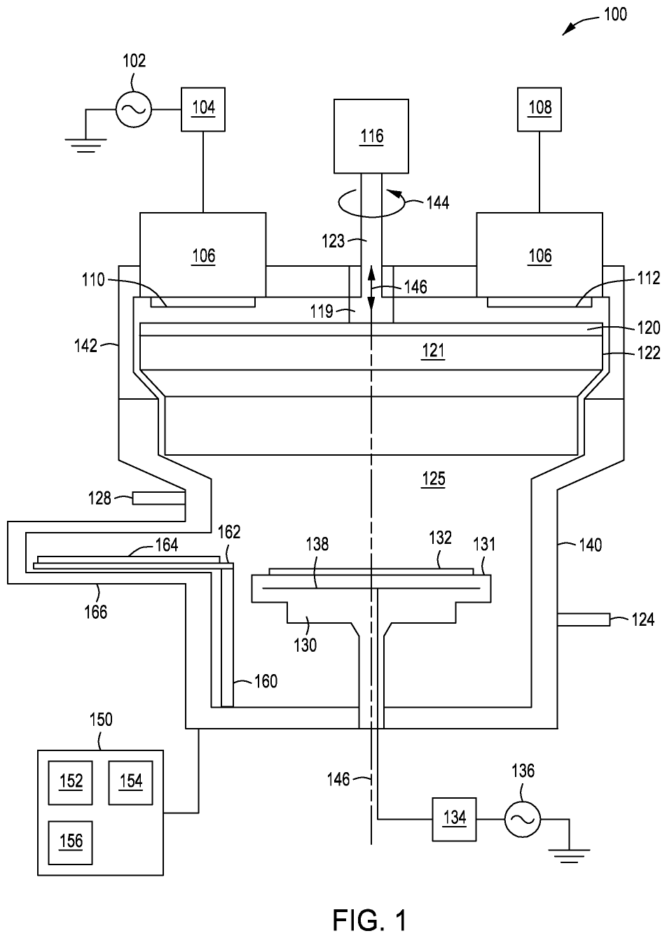

FIG. 1 is an example process chamber 100 in which the methods and apparatus of the present principles may be utilized. In some embodiments, a multiple cathode PVD chamber (e.g., process chamber 100) may be used. The process chamber 100 may include a plurality of cathodes 106 having a corresponding plurality of targets (dielectric targets 110 and/or metallic targets 112), attached to a chamber body 140 (for example, via a top adapter assembly 142). In some embodiments, the RF and DC cathodes are alternated in the top adapter assembly 142. In other embodiments, an RF cathode can be adjacent to other RF cathodes and likewise for DC cathodes. When multiple RF cathodes are used, the operating frequencies may be offset to reduce any interference during deposition processes. For example, in a three RF cathode configuration, the first RF cathode may be operated at a frequency of 13.56 MHz, the second RF cathode is operated at a frequency of 13.66 MHz (+100 kHz), and the third RF cathode is operated at a frequency of 13.46 MHz (−100 kHz). The offset is not required to be +/−100 kHz. The offset can be chosen based on crosstalk prevention for a given number of cathodes.

An RF cathode is typically used with the dielectric target 110 for dielectric film deposition on a wafer. A DC cathode is typically used with the metallic target 112 for pasting after the dielectric film deposition on the wafer. The pasting reduces the chance of particle formation and defects in the deposition film. During pasting, the substrate 132 is removed from a support surface 131 of a substrate support 130 and a shutter disk 164 is placed on the support surface 131 to protect the support surface 131 during pasting. The shutter disk 164 is stored in a shutter disk enclosure 166 and moved with a shutter disk arm 162 that rotates on a shaft 160. Having a process chamber with RF and DC cathodes allows for faster production of wafers because the pasting and dielectric deposition can be done in one chamber. In addition, having multiple cathodes of the same type, allows for greater pasting and deposition rates. A greater deposition rate means that a wafer spends less time in the chamber to achieve a certain film thickness. The reduced time in the chamber or dwell time reduction results in fewer wafer defects. In some embodiments, the metallic target 112 may be formed of a metal such as, for example, tantalum, aluminum, titanium, molybdenum, tungsten, and/or magnesium. The dielectric target 110 may be formed of a metal oxide such as, for example, magnesium oxide, titanium oxide, titanium magnesium oxide, and/or tantalum magnesium oxide. Other metals and/or metal oxides may be used. The sputter targets have a given life span and may be replaced during periodic maintenance.

As mentioned above, the process chamber 100 also includes the substrate support 130 to support the substrate 132. The process chamber 100 includes an opening (not shown) (e.g., a slit valve) through which an end effector (not shown) may extend to place the substrate 132 onto lift pins (not shown) for lowering the substrate 132 onto a support surface 131 of the substrate support 130. In some embodiments as shown in FIG. 1, the targets 110, 112 are disposed substantially parallel with respect to the support surface 131. The substrate support 130 includes a biasing source 136 coupled to a bias electrode 138 disposed in the substrate support 130 via a matching network 134. The top adapter assembly 142 is coupled to an upper portion of the chamber body 140 of the process chamber 100 and is grounded. A cathode 106 can have a DC power source 108 or an RF power source 102 and an associated magnetron. In the case of the RF power source 102, the RF power source 102 is coupled to a cathode 106 via an RF matching network 104.

A shield 121 is rotatably coupled to the top adapter assembly 142 and is shared by the cathodes 106. In some embodiments, the shield 121 includes a shield body 122 and a shield top 120. In some embodiments, the shield 121 has aspects of the shield body 122 and the shield top 120 integrated into one unitary piece. In some embodiments, the shield 121 can be more than two pieces. Depending on the number of targets that need to be sputtered at the same time, the shield 121 can have one or more holes to expose a corresponding one or more targets. The shield 121 advantageously limits or eliminates cross-contamination between the plurality of targets 110,112. The shield 121 is rotationally coupled to the top adapter assembly 142 via a shaft 123. The shaft 123 is attached to the shield 121 via a coupler 119. Additionally, since the shield 121 is rotatable, areas of the shield 121 that would not normally receive pasting are moved such that the areas can now be pasted, significantly reducing flaking of built-up deposition and particle formation. One or more shields may form a process kit. The process kit may be replaced at periodic intervals due to deposition buildup.

An actuator 116 is coupled to the shaft 123 opposite the shield 121. The actuator 116 is configured to rotate the shield 121, as indicated by arrow 144, and move the shield 121 up and down in the vertical direction along the central axis 146 of the process chamber 100, as indicated by arrow 145. During processing, the shield 121 is raised to an upward position. The raised position of the shield 121 exposes targets used during a processing step and also shields targets not used during the processing step. The raised position also grounds the shield for RF processing steps. The process chamber 100 further includes a process gas supply 128 to supply a process gas to an internal volume 125 of the process chamber 100. The process chamber 100 may also include an exhaust pump 124 fluidly coupled to the internal volume 125 to exhaust the process gas from the process chamber 100. In some embodiments, for example, the process gas supply 128 may supply oxygen and/or inert gas to the internal volume 125.

A controller 150 generally includes a Central Processing Unit (CPU) 152, a memory 154, and a support circuit 156. The CPU 152 may be any form of a general-purpose computer processor that can be used in an industrial setting. The support circuit 156 is conventionally coupled to the CPU 152 and may comprise a cache, clock circuits, input/output subsystems, power supplies, and the like. Software routines, such as a method as described above may be stored in the memory 154 and, when executed by the CPU 152, transform the CPU 152 into a specific purpose computer (controller 150). The software routines may also be stored and/or executed by a second controller (not shown) that is located remotely from the process chamber 100.

The memory 154 is in the form of computer-readable storage media that contains instructions, when executed by the CPU 152, to facilitate the operation of the semiconductor processes and equipment. The instructions in the memory 154 are in the form of a program product such as a program that implements the apparatus of the present principles. The program code may conform to any one of a number of different programming languages. In one example, the disclosure may be implemented as a program product stored on a computer-readable storage media for use with a computer system. The program(s) of the program product define functions of the aspects. Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the substrate heating system described herein, are aspects of the present principles.

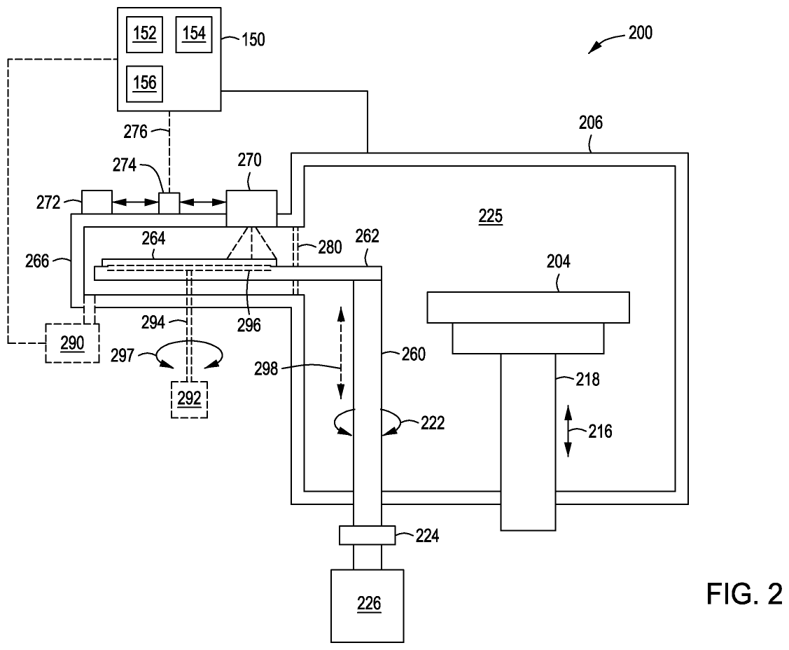

FIG. 2 depicts a cross-sectional view 200 of a portion of a process chamber in accordance with some embodiments. A shutter disk assembly may include a shutter disk 264 and a shutter disk arm 262. In some embodiments, the shutter disk assembly may also include a shaft 260 with a clockwise and counter-clockwise rotation 222 capability, a shaft sensor 224 for detecting a rotational angle of the shutter disk assembly, and/or an actuator 226 for providing rotational force to rotate the shaft 260 to move the shutter disk arm 262 and/or the shutter disk 264 from a shutter disk enclosure 266 to a substrate support 204 in a chamber housing 206 for processing procedures. The shutter disk 264 may be placed on the substrate support 204 to protect the surface of the substrate support 204 during processing such as cleaning and/or pasting and the like. The substrate support 204 includes a feedthrough assembly 218 which supports the substrate support 204 and also provides electrical connections and/or cooling liquids, etc. The substrate support 204 may move up and down indicated by arrow 216 during processing.

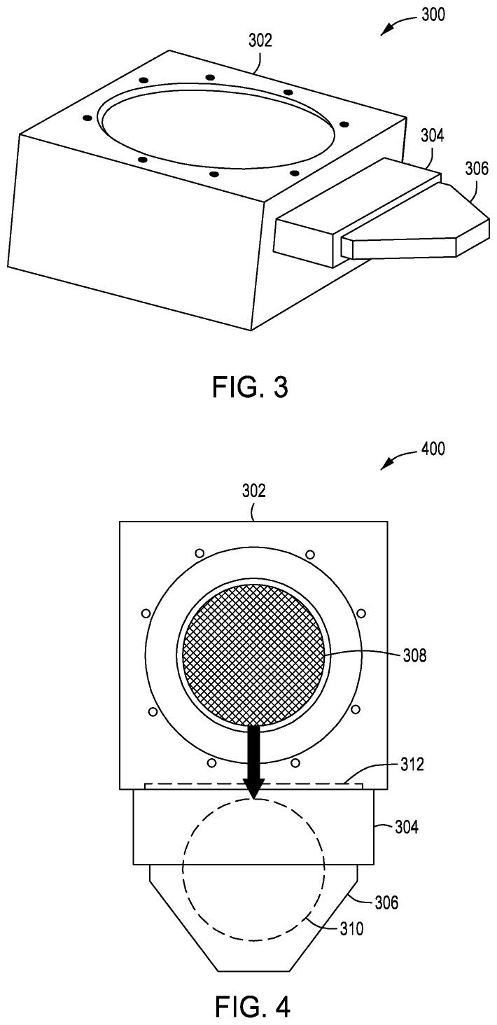

In some embodiments, the shutter disk enclosure 266 includes at least one sensor 270 that is integrated into the shutter disk enclosure 286. The sensor 270 is configured to determine at least one film property of a material deposited onto the shutter disk after a process, such as, for example, a pasting process that occurs in an internal processing volume 225 of the chamber housing 206. In some embodiments, the sensor 270 may include an spectroscopy measurement sensor such as, for example, a reflectometry sensor. In some embodiments, the sensor 270 may include a film morphology sensor. In some embodiments, the sensor 270 may include a film thickness sensor. In some embodiments, the sensor 270 may include an X-ray fluorescence (XRF) analyzer that may be configured to determine, for example, a magnesium-to-oxygen ratio of a magnesium oxide (MgO) material deposited onto the shutter disk 264 during a pasting process. In some embodiments, the sensor 270 may include a mixture of sensor types to enable detection of multiple film properties simultaneously. The sensor 270 may be formed as part of the shutter disk enclosure 266 as depicted in an isometric view 300 of FIG. 3 which shows a chamber housing 302 with a sensor 304 disposed between a shutter garage 306 and the chamber housing 302. The shutter disk enclosure 266 may also include a memory 272 that is in communication with the sensor 270. The memory 272 is used by the sensor 270 to store information such as, for example, data obtained with regard to the material deposited on the shutter disk 264. In some embodiments, the memory 272 may be integrated into the sensor 270 or may be separate from the sensor 270. The shutter disk enclosure 266 may also include a communication port 274 that may be configured to access the memory 272 and/or real-time data from the sensor 270 by, for example, the controller 150. The communication path 276 from the communication port 274 may be, for example, a wired path and/or a wireless path and the like including, Wi-Fi, Bluetooth, etc. In some embodiments, the communication port 274 may be part of the sensor 270.

In some embodiments, the shutter disk 264 is moved from the internal processing volume 225 and stored in the shutter disk enclosure 266 before the sensor 270 takes a reading at only a single position on the shutter disk 264. In some embodiments, the sensor 270 is activated as soon as the shutter disk 264 enters the shutter disk enclosure 266. The sensor 270 takes multiple readings at multiple shutter disk locations as the shutter disk 264 moves by the sensor 270 as depicted in FIG. 4. FIG. 4 shows a top down view 400 of a first shutter disk 308 on a substrate support in an internal processing volume being moved (new position shown by dotted substrate outline 310) into a shutter garage 306 with a sensor 304. In some embodiments, the shaft sensor 224 may be used in conjunction with the sensor 270 to control the rate and/or to pause the shutter disk assembly to take readings at different locations on the shutter disk 264 without introducing motion related aberrations in the sensor readings.

In some embodiments, the shutter disk enclosure 266 may also include an optional platform 296 that is connected to an optional rotatable shaft 294 as indicated by arrow 297. An optional drive assembly 292 may be used to rotate the optional rotatable shaft 294 and the optional platform 296. The optional rotatable shaft 294 and the optional platform 296 may operate independent of the shutter disk arm 262. The shutter disk arm 262 may place the shutter disk on the optional platform 296 by rotating the shutter disk arm 262 into position in the shutter disk enclosure 266 and lowering 298 the shaft 260 of the shutter disk assembly. The sensor 270, in the shutter disk rotatable configuration, can take one or more readings of a material deposited on the shutter disk 264 as the shutter disk 264 rotates near the sensor 270.

In some embodiments, the sensor 270 may operate more efficiently if the environment within the shutter disk enclosure 266 is adjusted. In some embodiments, an optional pump assembly 290 may be used in conjunction with an optional movable sealing plate 280 to create a sealed environment within the shutter disk enclosure 266. The sealed environment may be used to control parameters such as, for example, pressure within the shutter disk enclosure 266 independent of the environment in the internal processing volume 225 of the chamber housing 206. A sealing plate 312 is also depicted in FIG. 3. The optional pump assembly 290 may be in communication with the controller 150 to assist in producing the environmental changes.

Although examples used herein may depict top surface sensors on a shutter disk, one skilled in the art can appreciate that the sensors may also be located on the bottom surface of the shutter disk as well. Likewise, any inductive charging systems may also be positioned above a shutter disk as well.

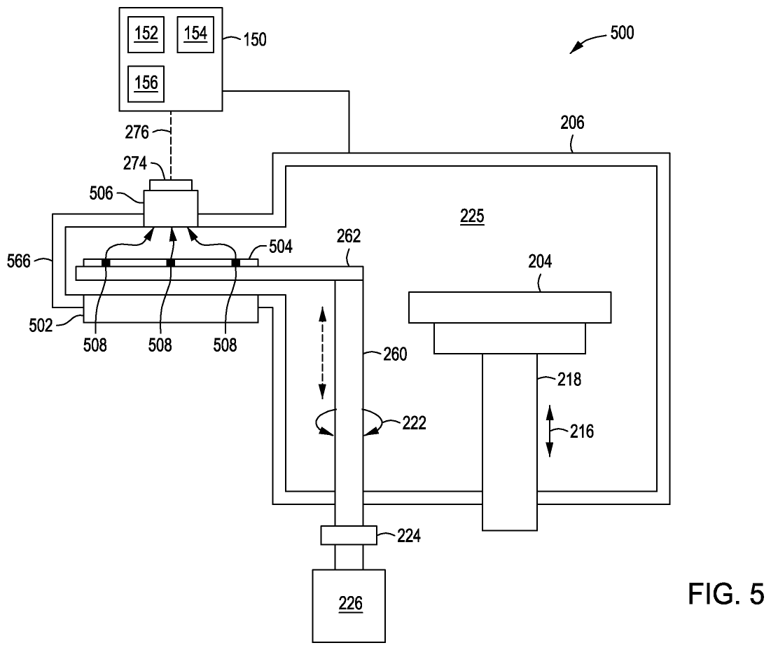

FIG. 5 depicts a cross-sectional view 500 of a portion of a process chamber in accordance with some embodiments. In some embodiments, the shutter disk enclosure 566 may also include the communication port 274 that may be configured to access the memory 272 by, for example, the controller 150. In some embodiments, the communication port 274 may allow direct communication with the sensors 508 on the shutter disk 504 to upload sensor data directly from the sensors 508, bypassing the enclosure memory 506. The communication path 276 from the communication port 274 may be, for example, a wired path and/or a wireless path and the like including, Wi-Fi, Bluetooth, etc. The communication port 274 may be part of the enclosure memory 506 (shown) or separate from the memory (not shown). In some embodiments, at least one sensor 508 is disposed on or into a shutter disk 504. The sensor 508 is able to determine at least one film property from a material deposited on the shutter disk 504 during or after a process in the internal processing volume 225 of the chamber housing 206. Information relating to the film property is storable in the shutter disk 504 and is then uploaded to the enclosure memory 506 when the shutter disk 504 returns to the shutter disk enclosure 566. In some embodiments, the sensor 508 in the shutter disk 504 will be energized by an inductive charging system 502 integrated into the shutter disk enclosure 566. Memory in the shutter disk 504 may be a single memory or include memories for each individual sensor.

In some embodiments, the sensor 508 may be a Micro-Electro-Mechanical System (MEMS) type sensor. The sensor 508 may include a sensor array that uses resonance across a whole surface of the shutter disk 504 to determine a deposited film thickness. As the thickness of the deposited material increases, the frequency shifts, providing an indicator of the change in thickness. In some embodiments, the sensor 508 may include a plurality of different types of sensors or sensors with different ranges of detection. For example, the sensor 508 may include a sensor A which has a thickness detection range of 0 to 10 angstroms, a sensor B which has a thickness detection range of 8 to 20 angstroms, and a sensor C which has a thickness detection range of 19 to 100 angstroms. Having variable ranges for the sensors allows for a large range of thickness detection which would allow that shutter disk to be used for a greater amount of time before needing the depositions to be removed or the shutter disk to be replaced. In some embodiments, the sensor 508 may include sensors that detect composition of and/or internal structures of a deposition on the shutter disk 504. Sensors that detect composition of the deposition may be used to determine oxygen levels of the deposition materials. Sensors that detect internal structures may be used to determine a crystalline structure of the deposition material and the like. In some embodiments, the sensors may utilize electrical measurement to determine film properties. In some embodiments, the sensors 508 may be replaceable and/or reconfigurable. In some embodiments, the sensor mounting may be standardized to allow a mixture of sensor types and/or sensor placement on the shutter disk 504. Shutter disk “blanks” can then be configured based on a process or chamber type and the like, significantly reducing the costs of a sensor based shutter disk as the core disk is configurable and can be used across a wider range of processes and chambers.

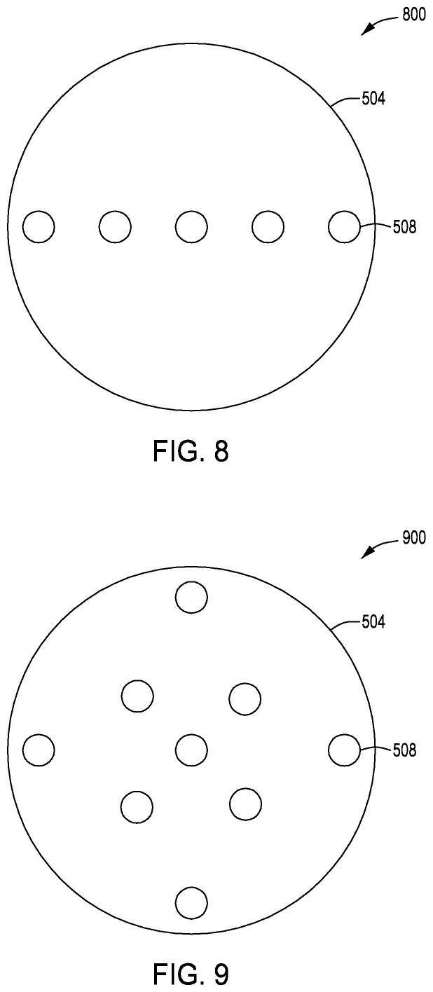

In some embodiments, the sensors 508 may include a plurality of sensors arranged in different patterns. FIG. 8 depicts a top down view 800 of the shutter disk 504 with a linearly aligned sensor pattern in accordance with some embodiments. The linearly aligned sensor pattern may be used to determine a film thickness or profile across the shutter disk 504 to check, for example, edge thickness and center thickness. FIG. 9 depicts a top down view 900 of the shutter disk 504 with a dispersed sensor pattern in accordance with some embodiments, the dispersed sensor pattern may be used to determine film uniformity over the whole surface of the shutter disk 504. One skilled in the art will understand that many other different patterns may be used based on the type of film properties that are to be measured.

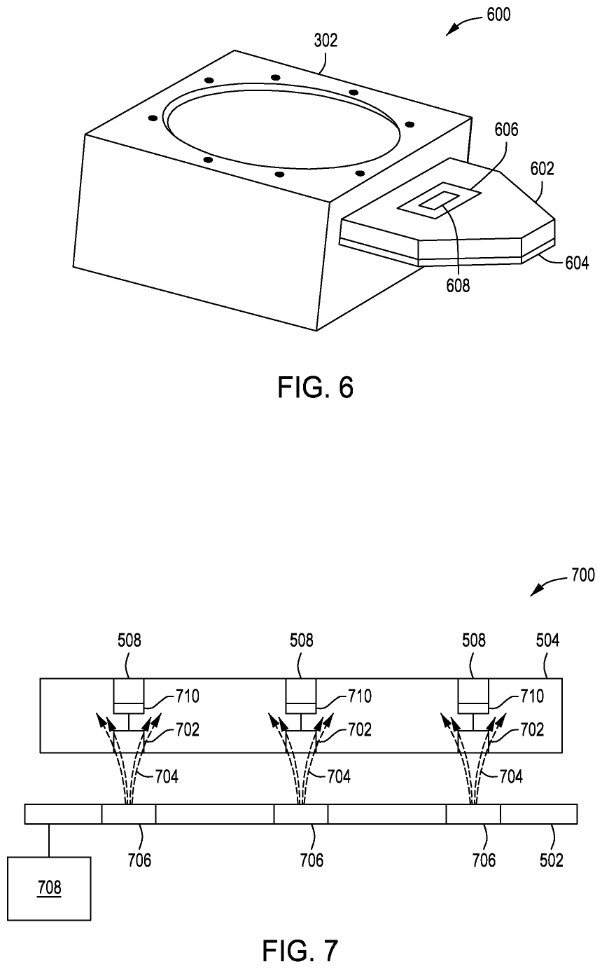

FIG. 6 depicts an isometric view 600 of a chamber housing 302 with a memory 606 and inductive charging system 604 integrated into a shutter disk enclosure 602 in accordance with some embodiments. In some embodiments, a communication port 608 will provide external access to information obtained from the sensors on the shutter disk as described above. FIG. 7 depicts a cross-sectional view of the shutter disk 504 with integrated sensors 508 interacting with the inductive charging system 502 in accordance with some embodiments. In some embodiments, the sensors 508 in the shutter disk 504 use at least one power source 702 to provide energy to the sensors 508 and/or local sensor memory 710 when the shutter disk 504 is in the internal processing volume. The local sensor memory 710 allows the sensors 508 to store sensor data on the shutter disk 504 for uploading to the enclosure memory 506 when the shutter disk 504 is returned to the shutter disk enclosure 566. In some embodiments, the local sensor memory 710 is federated into separate memories for each sensor (shown) and/or is a single memory for multiple sensors on the shutter disk 504 (not shown). The power source 702 may be a single power source for multiple sensors (not shown) or include multiple smaller power sources for individual sensors (shown). The power source 702 may include a capacitive element to hold a charge and an inductive element (e.g., winding) that is excited by a magnetic field 704 generated by an inductive power element 706 of the inductive charging system 502. The inductive charging system 502 may also include a power supply 708 that excites the inductive power element 706 to generate the magnetic fields that excite the inductive element of the power source 702.

One skilled in the art can appreciate that, in some embodiments, a shutter disk with sensors may also be used in conjunction with a shutter disk enclosure with sensors. In some embodiments, the shutter disk sensors may operate in conjunction with the shutter disk enclosure sensors to produce a more accurate deposition film property. For example, film uniformity data may be gathered in discrete locations by the shutter disk sensors and confirmed by scanning sensors in the shutter disk enclosure as the shutter disk is moved into the shutter disk enclosure. In some embodiments, the shutter disk sensors and the shutter disk enclosure sensors may operate to provide information in regard to different aspects of the deposition film property (e.g., film thickness and film morphology, etc.) providing more film property data than by using the shutter disk sensors alone or by using the shutter disk enclosure sensors alone.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. An apparatus for monitoring deposition, comprising:
a process chamber with an internal processing volume;
an enclosure disposed external to the internal processing volume, the enclosure is configured to accept a shutter disk when the shutter disk is not in use in the internal processing volume;
a shutter disk arm configured to move the shutter disk back and forth from the enclosure to the internal processing volume; and
at least one sensor integrated into the enclosure, the at least one sensor is configured to determine at least one film property of a material deposited on the shutter disk after a pasting process in the internal processing volume.

2. The apparatus of claim 1, further including:
a memory disposed in the enclosure that accepts data associated with the at least one film property from the at least one sensor.

3. The apparatus of claim 2, further including:
a communication port disposed in the enclosure that connects the memory or the at least one sensor to an external device, wherein the communication port transfers stored data from the memory or real-time data from the at least one sensor and includes wired or wireless data transfers.

4. The apparatus of claim 1, wherein the at least one sensor includes a spectroscopy sensor, a film morphology sensor, or a film thickness sensor.

5. The apparatus of claim 4, wherein the spectroscopy sensor includes an X-ray fluorescence (XRF) analyzer that determines the at least one film property of the material deposited on at least an upper surface the shutter disk.

6. The apparatus of claim 5, wherein the material is magnesium oxide (MgO) and the at least one film property includes a magnesium-to-oxygen ratio of the MgO.

7. The apparatus of claim 1, wherein the shutter disk arm is configured to rotate the shutter disk within the enclosure such that more than one location on a surface of the shutter disk is exposed to the at least one sensor.

8. The apparatus of claim 1, wherein the at least one sensor is configured to detect the at least one film property as the shutter disk enters the enclosure.

9. The apparatus of claim 1, wherein the enclosure includes a movable sealing plate that divides an internal volume of the enclosure from the internal processing volume.

10. The apparatus of claim 9, wherein the enclosure is configured to be pressurized independent of the internal processing volume such that data obtained by the at least one sensor with regard to the at least one film property is enhanced.

11. An apparatus for monitoring deposition, comprising:
a process chamber with an internal processing volume;
an enclosure disposed external to the internal processing volume, the enclosure is configured to accept a shutter disk when the shutter disk is not in use in the internal processing volume;
a shutter disk arm configured to move the shutter disk back and forth from the enclosure to the internal processing volume; and
at least one sensor integrated into the shutter disk, the at least one sensor is configured to determine at least one film property of a material deposited on the shutter disk after a pasting process in the internal processing volume.

12. The apparatus of claim 11, further comprising:
a power source integrated into the shutter disk, wherein the power source is configured to energize the at least one sensor; and
an inductive charging system integrated into the enclosure, wherein the inductive charging system is configured to energize the power source for the at least one sensor when the shutter disk is placed within the enclosure.

13. The apparatus of claim 11, further comprising:
a first memory integrated into the shutter disk, wherein the first memory is configured to store data associated with the at least one film property from the at least one sensor.

14. The apparatus of claim 13, further comprising:
a second memory disposed in the enclosure that accepts data associated with the at one least film property from the first memory via a wired or wireless transfer when the shutter disk is placed within the enclosure.

15. The apparatus of claim 14, further including:
a communication port disposed in the enclosure that connects to the second memory or to the first memory, wherein the communication port transfers stored data from the second memory or first memory and is configured to perform wired or wireless data transfers.

16. The apparatus of claim 11, wherein the at least one sensor is a plurality of sensors forming a sensor array on the shutter disk.

17. The apparatus of claim 16, wherein the sensor array includes a resonance array configured to determine a thickness of the material based on frequency shifts.

18. The apparatus of claim 11, wherein the material is magnesium oxide (MgO) and the at least one sensor is configured to determine a magnesium-to-oxygen ratio of the MgO.

19. An apparatus for monitoring deposition, comprising:
an enclosure configured to be mounted external to an internal processing volume of a processing chamber, wherein the enclosure is configured to accept a shutter disk when the shutter disk is not in use in the internal processing volume;
at least one sensor integrated into the enclosure, the at least one sensor is configured to determine at least one film property of a material deposited on the shutter disk after a pasting process in the internal processing volume;
a memory disposed in the enclosure, wherein the memory is configured to accept data associated with the at least one film property from the at least one sensor; and
a communication port disposed in the enclosure, wherein the communication port transfers stored data from the memory or real-time data from the at least one sensor and includes wired or wireless data transfers.

20. The apparatus of claim 19, wherein the at least one sensor includes an X-ray fluorescence (XRF) analyzer that is configured to determine a magnesium-to-oxygen ratio of MgO deposited on the shutter disk or a micro-electromechanical system sensor configured to determine thickness of a deposition layer on the shutter disk.
